(19) United States
(12) Patent Application Publication
(10) Pub. No.: US 2012/0201974 A1
(43) Pub. Date: Aug. 9, 2012

(54) METHOD FOR THE HIGH-TEMPERATURE-RESISTANT BONDING OF OXYGEN-PERMEABLE OXIDE CERAMICS BASED ON SUBSTITUTED ALKALINE-EARTH COBALTATES BY MEANS OF DOPING-SUPPORTED DIFFUSIVE REACTIVE SINTERING

(75) Inventors: Ralf Kriegel, Kahla (DE); Robert Kircheisen, Jena (DE); Katrin Ritter, Hermsdorf (DE)

(73) Assignee: Fraunhofer Gesellschaft zur Foerderung der angewandten Forschung e.V., Munich (DE)

(21) Appl. No.: 13/501,753

(22) PCT Filed: Oct. 14, 2010
(86) PCT No.: PCT/DE10/50078

§ 371 Date: Apr. 13, 2012

(30) Foreign Application Priority Data
Oct. 16, 2009 (DE) 10 2009 050 019.7

(51) Int. Cl. B05D 3/02; B05D 3/08; B05D 1/08; C23C 16/00; C23C 16/44

(52) U.S. Cl. 427/543; 427/372.2; 427/255.11; 427/569; 427/446; 427/553; 427/554; 427/294

(57) ABSTRACT

A method for high temperature resistant bonding of oxygen permeable oxide ceramics of substituted alkaline earth cobaltates by doping assisted diffusive reaction sintering includes providing at least one joining surface of the oxygen permeable ceramics with a Cu-containing additives. At least a join area of the oxygen permeable ceramics is subsequently heated, under loading through forces, to a temperature up to 250 K below a customary sintering temperature of the oxygen-permeable ceramics. The join area is held under the loading at the temperature for 0.5 to 10 hours.

### CROSS REFERENCE TO RELATED APPLICATIONS

This application is a U.S. National Phase application under 35 U.S.C. §371 of International Application No. PCT/DE2010/050078, filed on Oct. 14, 2010, and claims benefit to German Patent Application No. DE 10 2009 050 019.7, filed on Oct. 16, 2009. The International Application was published in German on Apr. 21, 2011 as WO 2011/044893 A1 under PCT Article 21 (2).

### FIELD

The invention is directed to a method for the high temperature resistant bonding or joining of oxide ceramic structural component parts of mixed conducting oxide ceramics. In this way, ceramics based on substituted alkaline earth cobaltates can be permanently bonded to one another so as to be resistant to high temperature and, when using dense ceramic structural component parts, in a gas-tight manner so that complex structural component parts can be constructed therefrom. This opens up new possibilities for the structural optimization of membrane structural component parts, for the connection of gas lines, for increasing the area density of membranes and, therefore, oxygen permeation with respect to the reaction volume.

### BACKGROUND

Methods exist for bonding various sintered ceramics to one another or to metals by brazing processes such as active brazing or reactive air brazing (RAB, WO 03/063 186 A1). Alternatively, glass brazes are also used, and ceramic pastes or powders (EP 1 816 122 A2) or metallic coatings (U.S. Pat. No. 5,230,924 A) are applied to the joining surfaces. Subsequently, the ceramic components are annealed, with or without loading, so that a bonding of the structural component parts is achieved through interdiffusion processes or by reactive sintering. It is also possible to join unsintered components in this way (U.S. Pat. No. 4,767,479 A). A method for joining ceramic hollow fibers of oxide ceramics in which the bond is achieved by forming sinter bridges between the joining locations or by means of ceramic adhesive is described in EP 1 846 345 B1.

Mixed conducting ceramics are used for separating oxygen from air at temperatures of 700° C. to 1000° C. The mixed conductors with the highest oxygen permeation are based on substituted alkaline earth cobaltates such as SrCo_{0.8}Fe_{0.2}O_{3-δ}, Ba_{0.5}Sr_{0.5}Co_{0.8}Fe_{0.2}O_{3-δ}, La_{0.2}Sr_{0.8}Co_{0.6}Fe_{0.4}O_{3-δ}, Ba_{0.8}La_{0.2}Co_{0.6}Fe_{0.4}^{O}_{3-δ}Sr_{0.6}La_{0.4}Co_{0.2}Fe_{0.8}O_{3-δ}(J. F. Vente et al.: Performance of functional perovskite membranes for oxygen production, J. of Membr. Sc. 276 (2006), 178), BaCo_{0.6}Fe_{0.2}Zr_{0.2}O_{3-δ} and Ba_{0.5}Sr_{0.5}Co_{0.6}Fe_{0.2}Zr_{0.2}O_{3-δ} (J. Sunarso et al., Mixed ionic-electronic conducting (MIEC) ceramic-based membranes for oxygen separation. J. of Membr. Sc. 320 (2008), 13) as well as SrCo_{0.8}Nb_{0.2}O_{3-δ} (K. Zhang et al.: Systematic investigation on new SrCo_{1-y}Nb_{y}O_{3-δ} ceramic membranes with high oxygen semi-permeability, J. of Membr. Sc. 323 (2008), 436).

Tubular mixed conducting membrane components are preferably connected on only one side in order to prevent tensions due to different thermal expansion of the membranes and connection parts. For this reason, tubular membranes which are closed on one side are needed. However, the complexity of the membrane structural component parts is limited by conventional ceramic shaping methods such as extrusion, uniaxial or isostatic pressing, or injection molding. For example, isostatic pressing of small-diameter membrane tubes which are closed on one side does not allow large tube lengths or complex inner geometry. Therefore, maximization of the area density of the membranes is severely limited. For the extrusion of single-channel or multichannel tubes which are closed on one side, each tube diameter requires its own closure die in addition to the nozzle, which increases the costs of the process or significantly restricts the choice of tube geometry.

In the construction of planar systems out of ceramic foils, joining to gas-tight cells and the connection of the cells to one another are the crucial manufacturing steps because the areas to be joined are substantially larger than in tubular systems. Therefore, the likelihood that leaks will occur is substantially higher than in tubular systems. Suitable methods for gas-tight joining are therefore an indispensible prerequisite for the construction of planar systems for oxygen separation.

In order to combine mixed conducting membranes with gas lines, gas distributors and internal heat exchangers, a gas-tight, high temperature resistant bonding of widely differing structural component parts is required. Mixed conductors with high oxygen permeation have a very high thermal expansion on which the chemical expansion is additionally superimposed in a nonlinear manner. Other material compositions are therefore unsuitable for these adjoining structural component parts because of the distinctly differing expansion behavior. A promising solution is to fabricate these adjoining structural component parts from the same material also and to bond these ceramic components to one another. Appropriate joining methods are needed for this purpose.

For joining mixed conducting ceramics to one another, active brazes are excluded from the outset because they must be applied under vacuum or in inert gas atmospheres. Moreover, these brazes are not stable over the long term under the oxidizing working conditions of oxygen permeation (K. S. Weil et al., Brazing as a means of sealing ceramic membranes for use in advanced coal gasification processes, Fuel 85 (2006) 156). By contrast, RAB brazes are oxidatively stable but sublimate under low pressure and at high working temperatures above 800° C. so that the joint becomes leaky after a relatively brief service life. Further, RAB brazes melt at about 940° C. This can be considered as critical with regard to safety aspects for the peak temperatures occurring during O₂ separation.

Glass brazes, on the other hand, rely on acidic oxide components which sometimes react very violently with mixed conducting ceramics because of the latter's high alkaline earth content. Also, their softening temperatures are too low for working temperatures above 850° C. The reactivity of glass brazes can be mitigated by mixing with ceramic powder, and the crystallization of glass brazes can also be deliberately used for mechanical strengthening of the connections; however, persistent reactive changes must be expected because of the high reactivity of the substituted alkaline earth cobaltates. This results, for one, in reduced oxygen permeation and, for another, in increased failures. Owing to the different expansion behavior of glass braze and ceramic components and the high rigidity of crystallized joint areas, the thermal cycling (starting and stopping) of an installation in particular must be considered especially critical.

### SUMMARY

In an embodiment, the present invention provides a method for high temperature resistant bonding of oxygen permeable oxide ceramics of substituted alkaline earth cobaltates by doping assisted diffusive reaction sintering including providing at least one joining surface of a joint area of the oxygen permeable ceramics with a Cu-containing additives. At least the joint area is subsequently heated, under loading through force, to a temperature up to 250 K below a customary sintering temperature of the oxygen-permeable ceramics. The joint area is held under the loading at the temperature for 0.5 to 10 hours.

### DETAILED DESCRIPTION

An embodiment of the invention provides a method for the high temperature resistant bonding or joining of oxide ceramic structural component parts of mixed conducting oxide ceramics. In this way, ceramics based on substituted alkaline earth cobaltates can be permanently bonded to one another so as to be resistant to high temperature and, when using dense ceramic structural component parts, in a gas-tight manner so that complex structural component parts can be constructed therefrom. This opens up new possibilities for the structural optimization of membrane structural component parts, for the connection of gas lines, for increasing the area density of membranes and, therefore, oxygen permeation with respect to the reaction volume.

An aspect of the present invention provides a possibility by which high temperature resistant bonds of ceramic structural component parts of mixed conducting substituted alkaline earth cobaltates can be produced, wherein these bonds are gas-tight when dense membrane components are used.

In an embodiment, the present invention provides a method for the high temperature resistant bonding of oxygen-permeable oxide ceramics of substituted alkaline earth cobaltates by means of doping-assisted diffusive reaction sintering in that at least one of the joining surfaces of the oxygen-permeable oxide ceramics is provided with Cu-containing additives, and in that at least the joint area is subsequently heated under loading by forces to temperatures up to 250 K below the customary sintering temperature of the oxygen-permeable oxide ceramics and is held under loading at this temperature for 0.5 hours to 10 hours.

In so doing, the load can be applied, for example, through weight force, through pressure force or a force brought about through volume changes of materials or through combinations of different forces.

The method is limited to substituted alkaline earth cobaltates because the Cu-containing additives that are used are compatible only with these basic ceramics.

An advantage of the invention is that additions of copper oxide during the sintering of substituted alkaline earth cobaltates lead to noticeable reductions in the sintering temperature accompanied by intermediate formation of liquid phases. Copper-containing compounds or elementary copper also exhibit this effect because they are converted to CuO or Cu₂O when heated in air. In the course of sintering, substantial amounts of copper dissolve in the alkaline earth cobaltates without forming foreign phases. It is likewise advantageous that the oxygen permeation of the mixed conductors based on the substituted alkaline earth cobaltates is influenced only slightly by doping with copper.

Therefore, ceramic components of substituted alkaline earth cobaltates can be joined so as to be gas-tight and enduringly stable under high temperatures in that one or both joining surfaces is/are coated or printed with a copper-containing paste. Further, it is possible to apply a metallization of copper through conventional coating methods or to arrange a copper-containing joining foil in the joint gap. Subsequently, the ceramic parts to be joined are loaded by a weight and heated to a temperature of up to 250 K below the customary sintering temperature of the structural component part. In this way, deformations of the structural component parts can be prevented to a great extent. The type of Cu compound is of secondary importance when heating in air because thin Cu foils and also Cu compounds are converted to CuO and Cu₂O, respectively, until the joining temperature is reached. The exact joining temperature depends substantially on the specific chemical composition of the mixed conductors and, like the added amount of copper-containing additives, is determined empirically.

The invention will be described more fully in the following with reference to embodiment examples

### Embodiment Example 1

### Gas-Tight One-Sided Closure of Membrane Tubes of BSCF5582

A densely sintered tube of BSCF5582 (Ba_{0.5}Sr_{0.5}Co_{0.8}Fe_{0.2}O_{3-δ}) is cut in a straight manner by a diamond cutting disk on a cutting machine. A cylindrical, dense tablet of the same material having a suitable diameter is flat ground on one side. The tablet is placed in the joining furnace on a ball-bearing mounted ZrO₂ plate. A foil ring made of copper foil having a foil thickness of 6 μm is placed on the tablet and the membrane tube is placed on this foil. The upper end of the membrane tube is loosely guided into a nozzle brick and loaded by a weight of 0.5 kg. This is followed by heating to 1000° C. at 3 K/min, holding for 2 hours, and cooling at 3 K/min or at the furnace cooling rate. The closure of the membrane tube is mechanically stable and gas-tight, i.e., its He leakage rate is less than 10⁻⁹ mbar·1/s. The connection can be thermally cycled as required.

### Embodiment Example 2

### Gas-tight Joining of Membrane Tubes of BSCFZ55622

Two densely sintered tubes of BSCFZ55622 (Ba_{0.5}Sr_{0.5}Co_{0.6}Fe_{0.2}Zr_{0.2}O_{3-δ}) are cut off in a straight manner by a diamond cutting disk on a cutting machine. Both tubes are loosely fixed in the joining furnace through nozzle bricks. One joining surface is covered with a paste of 20 Ma-% Cu₂O in terpineol. Subsequently, the joining surfaces of both tubes are placed against one another and the upper tube is loaded by a weight of 0.5 kg. This is followed by heating to 120° C. at 3 K/min, holding for 30 minutes, then further heating to 1050° C., holding for 2 hours, and cooling at 3 K/min or at the furnace cooling rate. The joint of the membrane tubes is mechanically stable and gas-tight, i.e., the He leakage rate is less than 10⁻⁹ mbar·l/s. The connection can be thermally cycled as required.

### Embodiment Example 3

### One-Sided Closure of Dense Membrane Tubes of BCFZ622

A dense membrane tube made of BCFZ622 (BaCo_{0.6}Fe_{0.2}Zr_{0.2}O_{3-δ}) is cut off in a straight manner by a diamond cutting disk on a cutting machine. A cylindrical, dense tablet of the same material having a suitable diameter is flat ground on one side. The tablet is placed in the joining furnace on a ball-bearing mounted ZrO₂ plate. The edge region of the tablet is densely coated with a little CuO powder, the membrane tube is placed thereon and lightly rotated back and forth 2-3 times. The upper end of the membrane tube is loosely guided into a nozzle brick and loaded by a weight of 0.5 kg. This is followed by heating to 1030° C. at 3 K/min, holding for 2 hours, and cooling at 3 K/min or at the furnace cooling rate. The closure of the membrane tube is mechanically stable and gas-tight, i.e., its He leakage rate is less than 10⁻⁹ mbar·l/s. The connection can be thermally cycled as required.

### Embodiment Example 4

### Joining of Porous and Dense BSCF5582

A porous membrane tube made of BSCF5582 (Ba_{0.5}Sr_{0.5}Co_{0.8}Fe_{0.2}O_{3-δ}) is dry cut in a straight manner by a diamond cutting disk on a cutting machine. A cylindrical, densely sintered tablet of the same material having a suitable diameter is flat ground on one side. The tablet is placed in the joining furnace on a ball-bearing mounted ZrO₂ plate. A ring of thin Cu wire (A-φ approximately 0.30 mm) is arranged between the membrane tube and the tablet and the membrane tube is positioned. The upper end of the membrane tube is loosely guided into a nozzle brick and loaded by a weight of 0.5 kg. This is followed by heating to 1000° C. at 3 K/min, holding for 2 hours, and cooling at 3 K/min or at the furnace cooling rate. The closure of the membrane tube is mechanically stable. The connection can be thermally cycled as required.

### Embodiment Example 5

### One-sided Closure of Dense Membrane Tubes of LSCF2864

A dense membrane tube of LSCF2864 (La_{0.2}Sr_{0.8}Co_{0.6}Fe_{0.4}O_{3-δ}) is cut off in a straight manner by a diamond cutting disk on a cutting machine. A cylindrical tablet of the same material having a suitable diameter is flat ground on one side. The tablet is placed in the joining furnace on a ball-bearing mounted ZrO₂ plate. A joining surface is coated with a paste of 15 Ma-% CuO in terpineol, the membrane tube is then positioned and loaded by a weight of 0.5 kg. This is followed by heating to 120° C. at 3 K/min, holding for 30 minutes, then further heating to 1050° C., holding for 2 hours, and cooling at 3 K/min or at the furnace cooling rate. The closure of the membrane tube is mechanically stable and gas-tight, i.e., its He leakage rate is less than 10⁻⁹ mbar·l/s. The connection can be thermally cycled as required.

### Embodiment Example 6

### Gas-Tight, One-Sided Closure of Honeycombs of BSCF5582

A densely sintered honeycomb of BSCF5582 (Ba_{0.5}Sr_{0.5}Co_{0.8}Fe_{0.2}O_{3-δ}) with approximately 200 csi is cut in a straight manner by a diamond cutting disk on a cutting machine. A cylindrical, dense tablet of the same material having a suitable diameter is flat ground on one side and screen printed over its entire surface with a paste of 5 M-% Cu₂O in terpineol. The tablet is placed in the joining furnace on a ball-bearing mounted ZrO2 plate, the honeycomb is positioned and loaded by a weight of 1 kg. This is followed by heating to 120° C. at 3 K/min, holding for 30 minutes, then further heating to 1000° C., holding for 2 hours, and cooling at 3 K/min or at the furnace cooling rate. The closure of the honeycomb is mechanically stable and gas-tight, i.e., the He leakage rate is less than 10⁻⁹ mbar·l/s. The connection can be thermally cycled as required.

### Embodiment Example 7

### Gas-tight Bonding of Capillaries and Plates of BSCF5582 Making Use of Sintering Shrinkage Force

Seven densely sintered capillaries or hollow fibers of BSCF5582 (Ba_{0.5}Sr_{0.5}Co_{0.8}Fe0.2O_{3-δ}) are cut in a bundle in a straight manner by a diamond cutting disk on a cutting machine. Seven symmetrically arranged bore holes are drilled in a cylindrical tablet of the same material in unsintered or partially sintered state. The diameter of the bore holes is smaller than the outer diameter of the capillaries or hollow fibers taking into account the sintering shrinkage which is to be determined empirically. The continuous bore holes are counterbored from one side of the tablet to obtain stepped holes having an inner support edge for the capillaries or hollow fibers. The larger diameter of the stepped bore holes is selected in such a way that the resulting sintering shrinkage of the tablet during the joining process leads to a shrinkage of the cylindrical surfaces of the bore hole onto the capillaries or hollow fibers. A diameter which yields hole diameters that are 3-20% smaller than the outer diameter of the capillaries or hollow fibers after joining is advantageously selected for the larger bore hole. The cut ends of the capillaries or hollow fibers are thinly coated with a paste of 1 M-% Cu₂O in terpineol and are inserted into the holes. This is followed by heating to 120° C. at 3 K/min, holding for 30 minutes, then further heating to 980° C., holding for 1.5 hours, and cooling at 3 K/min or at the furnace cooling rate. As a result of the sintering shrinkage occurring in the tablet in relation to the thoroughly sintered capillaries or hollow fibers, the lateral cylinder surface of the bore holes is pressed on the outer wall of the capillaries or hollow fibers by sintering shrinkage forces so that a gas-tight bond is brought about between the structural component parts. The He leakage rate is less than 10⁻⁹ mbar·l/s. The connection can be thermally cycled as required.

The invention is not limited to the embodiments described herein; reference should be had to the appended claims.

1-8. (canceled)

9. A method for high temperature resistant bonding of oxygen permeable oxide ceramics of substituted alkaline earth cobaltates by doping assisted diffusive reaction sintering, the method including:
providing at least one joining surface of a joint area of the oxygen permeable ceramics with a Cu-containing additive;
subsequently heating at least the joint area, under loading through force, to a temperature up to 250 K below a customary sintering temperature of the oxygen-permeable ceramics; and
holding the joint area under the loading at the temperature for 0.5 to 10 hours.

10. The method recited in claim 9, wherein the substituted alkaline earth cobaltates include one of dense and porous alkaline earth cobaltates, the alkaline earth cobaltates having a composition of A₁₋ₓSEₓCo_{1-y}B_{y}O_{3-δ}, where
A represents Ca, Sr, Ba,
SE represents at least one of Pb, Na, K, Sc, Y and elements of the lanthanide group,
B represents at least one of Mg, Al, Ga, In, Sn, 3d period elements and 4d period elements,
x represents values from 0 to 0.6, y represents values from 0 to 0.6, and δ is a value yielded in accordance with the principle of electroneutrality.

11. The method recited in claim 9, wherein the copper-containing additives include copper compounds, copper oxides, copper metal, and mixtures of copper metal with other materials containing more than 1 Ma-% copper.

12. The method recited in claim 11, wherein the copper-containing additives are provided on the at least one joining surface by one of CVD, PVD, PECVD, sputtering, thermal spraying, sol-gel processes, screen printing and inkjet printing.

13. The method recited in claim 9, wherein the heating the joint area includes at least one of direct electric heating, indirect electric heating, flame heating, heating by lasers, center-frequency induction, high frequency induction, use of microwaves and use of heat radiators.

14. The method recited in claim 9, wherein the heating the joint area is carried out in gases with reduced or increased oxygen partial pressure.

15. The method recited in claim 9, wherein the heating the joint area is carried out under vacuum.

16. The method recited in claim 9 wherein the providing the at least one joining surface with Cu-containing additives includes coating or printing a Cu-containing paste on the at least one joining surface.

17. The method recited in claim 9, wherein the providing the at least one joining surface with Cu-containing additives includes applying metallization of copper to the at least one joining surface.

18. The method recited in claim 9, wherein the providing the at least one joining surface with Cu-containing additives includes disposing at least one of copper metal and copper containing compounds in a joint gap.
